(19) United States
(12) Patent Application Publication
(10) Pub. No.: US 2016/0293600 A1
(43) Pub. Date: Oct. 6, 2016

(54) SEMICONDUCTOR DEVICE

(71) Applicants: Jung-Gun YOU, Ansan-si (KR); Hyung-Jong LEE, Osan-si (KR); Chong-Kwang CHANG, Bucheon-si (KR); Sung-Min KIM, Daegu (KR)

(72) Inventors: Jung-Gun YOU, Ansan-si (KR); Hyung-Jong LEE, Osan-si (KR); Chong-Kwang CHANG, Bucheon-si (KR); Sung-Min KIM, Daegu (KR)

(21) Appl. No.: 14/995,511

(22) Filed: Jan. 14, 2016

(30) Foreign Application Priority Data
Apr. 2, 2015 (KR) 10-2015-0046764

(51) Int. Cl. H01L 27/088; H01L 27/02; H01L 23/535; H01L 29/06

(52) U.S. Cl. CPC H01L 27/0886; H01L 29/0649; H01L 27/0207; H01L 23/535

(57) ABSTRACT

A semiconductor device, including a first fin type pattern and a second fin type pattern defined by a trench, the first fin type pattern and the second fin type pattern extending in a first direction, the first fin type pattern and the second fin type pattern being closest to each other; a field insulation layer filling a portion of the trench; and a contact contacting the field insulation layer, the first fin type pattern, and the second fin type pattern, the contact having a bottom surface in a shape of a wave.

### CROSS-REFERENCE TO RELATED APPLICATION

Korean Patent Application No. 10-2015-0046764, filed on Apr. 2, 2015, in the Korean Intellectual Property Office, and entitled: “Semiconductor Device,” is incorporated by reference herein in its entirety.

### BACKGROUND

1. Field

Embodiments relate to a semiconductor device.

2. Description of the Related Art

As one scaling technology for increasing the density of a semiconductor device, a multi-gate transistor having a fin-shaped silicon body formed on a substrate and a gate formed on the surface of the fin-shaped silicon body has been proposed.

### SUMMARY

Embodiments may be realized by providing a semiconductor device, including a first fin type pattern and a second fin type pattern defined by a trench, the first fin type pattern and the second fin type pattern extending in a first direction, the first fin type pattern and the second fin type pattern being closest to each other; a field insulation layer filling a portion of the trench; and a contact contacting the field insulation layer, the first fin type pattern, and the second fin type pattern, the contact having a bottom surface in a shape of a wave.

The bottom surface of the contact contacting the field insulation layer between the first fin type pattern and the second fin type pattern may have a first point close to the first fin type pattern and a second point farther from the first fin type pattern than the first point, and a height ranging from a bottom of the trench to the first point may be greater than a height ranging from the bottom of the trench to the second point.

A top surface of the first fin type pattern, a top surface of the second fin type pattern, and a top surface of the field insulation layer may be curved surfaces in regions overlapping the contact.

An average thickness of the contact at a region where the contact overlaps with the top surface of the first fin type pattern may be a first thickness, and an average thickness of the contact at a region where the contact overlaps with the top surface of the field insulation layer between the first fin type pattern and the second fin type pattern may be a second thickness, and the second thickness may be greater than the first thickness.

The bottom surface of the contact may be continuous along the top surface of the first fin type pattern, the top surface of the field insulation layer, and the top surface of the second fin type pattern.

Sidewalls of the first fin type pattern and sidewalls of the second fin type pattern may be entirely surrounded by the field insulation layer in regions overlapping the contact.

A width of the first fin type pattern at a first height from the bottom of the trench may be a first width, a width of the first fin type pattern at a second height greater than the first height from the bottom of the trench may be a second width, and the first width may be greater than or equal to the second width.

The semiconductor device may further include a third fin type pattern extending in the first direction; and a gate electrode extending in a second direction different from the first direction, the gate electrode being on the first to third fin type patterns. The bottom surface of the contact may not be in contact with the third fin type pattern.

A height ranging from the bottom of the trench to the topmost part of the first fin type pattern in a region where the contact and the first fin type pattern cross each other may be a first height, and a height ranging from the bottom of the trench to the topmost part of the third fin type pattern in a region where an extension line of the contact extending in the second direction and the third fin type pattern cross each other may be a second height, and the second height may be greater than the first height.

The third fin type pattern may not be in contact with the contact.

The field insulation layer may include a first part between the first fin type pattern and the second fin type pattern, a second part corresponding to the first part of the field insulation layer in view of the first fin type pattern, and a third part corresponding to the first part of the field insulation layer in view of the second fin type pattern, and a height ranging from the bottom of the trench to a bottommost part of a top surface of the first part of the field insulation layer may be different from a height ranging from the bottom of the trench to a bottommost part of a top surface of the second part of the field insulation layer and a height ranging from the bottom of the trench to a bottommost part of a top surface of the third part of the field insulation layer.

The height ranging from the bottom of the trench to a bottommost part of a top surface of the first part of the field insulation layer may be greater than the height ranging from the bottom of the trench to the bottommost part of the top surface of the second part of the field insulation layer and the height ranging from the bottom of the trench to a bottommost part of a top surface of the third part of the field insulation layer.

The first fin type pattern may include a first part and a second part including a recess, the second part of the first fin type pattern may be at an opposite side of the first part of the first fin type pattern in the first direction, and the contact may fill the recess.

The semiconductor device may further include a gate electrode extending in a second direction different from the first direction and on the first part of the first fin type pattern; and a spacer on sidewalls of the gate electrode. A portion of the first fin type pattern may be interposed between the spacer and the contact.

Embodiments may be realized by providing a semiconductor device, including a fin type pattern group including a plurality of fin type patterns defined by a first trench, the fin type pattern group extending in a first direction, the plurality of fin type patterns arranged in a second direction different from the first direction; a field insulation layer filling a portion of the first trench; a gate electrode extending on the field insulation layer in the second direction, the gate electrode intersecting the fin type pattern group; an interlayer dielectric film on the field insulation layer, the interlayer dielectric film including a contact hole covering the fin type pattern group and the gate electrode, the contact hole extending in the second direction, the contact hole having a bottom surface defined by a top surface of the field insulation layer and a top surface of at least one fin type pattern, the bottom surface of the contact hole having a wave shape; and a contact filling the contact hole on at least one side of the gate electrode.

The contact may contact the top surface of the fin type pattern and the top surface of the field insulation layer.

The bottom surface of the contact hole defined by the top surface of the fin type pattern may have a ridge of a wave and the bottom surface of the contact hole defined by the top surface of the field insulation layer may include a valley of a wave.

The top surface of the fin type pattern group and the top surface of the field insulation layer exposed by the contact hole may be curved surfaces.

An average thickness of the contact at a region where the contact overlaps with the top surface of the fin type pattern group may be a first thickness and an average thickness of the contact at a region where the contact overlaps with the top surface of the field insulation layer may be a second thickness, and the second thickness may be greater than the first thickness.

The fin type pattern group may be in an active region defined by a second trench deeper than the first trench.

Embodiments may be realized by providing a semiconductor device, including a substrate including a first region and a second region; a first fin type pattern defined by a first fin type pattern in the first region of the substrate, the first fin type pattern extending in a first direction; a second fin type pattern defined by a second trench in the second region of the substrate, second fin type pattern extending in a second direction; a field insulation layer filling a portion of the first trench and a portion of the second trench on the substrate; a first gate electrode extending in a third direction different from the first direction on the first fin type pattern; a second gate electrode extending in a fourth direction different from the second direction on the second fin type pattern; a first source/drain including a first epitaxial layer on the second fin type pattern at opposite sides of the second gate electrode; a first contact contacting the field insulation layer and the first fin type pattern at opposite sides of the first gate electrode, the first contact having a bottom surface in a shape of a wave; and a second contact on the first source/drain, the second contact not contacting the field insulation layer.

The bottom surface of the first contact may be continuous along a top surface of the first fin type pattern and a top surface of the field insulation layer.

A height ranging from the bottom of the first trench to a bottommost part of the first contact may be smaller than a height ranging from a bottom of the second trench to a bottommost part of the second contact.

The second fin type pattern may include a recess at opposite sides of the second gate electrode and the first epitaxial layer may fill the recess.

The first epitaxial layer may be along a profile of the second fin type pattern protruding above the top surface of the field insulation layer.

A portion of the outer circumferential surface of the first epitaxial layer may extend along the top surface of the field insulation layer.

The semiconductor device may further include a third fin type pattern defined by a third trench, the third fin type pattern extending in a fifth direction in a third region of the substrate; a third gate electrode extending in a sixth direction different from the fifth direction on the third fin type pattern; a second source/drain including a second epitaxial layer on the third fin type pattern at opposite sides of the third gate electrode; and a third contact on the second source/drain, the third contact not contacting the field insulation layer. A height ranging from the bottom of the second trench to a bottommost part of the second contact may be different from a height ranging from the bottom of the third trench to a bottommost part of the third contact.

The second region of the substrate may be a PMOS region and the third region of the substrate may be an NMOS region.

The height ranging from the bottom of the second trench to a bottommost part of the second contact may be different from the height ranging from a bottom of the third trench to a bottommost part of the third contact.

A portion of the outer circumferential surface of the second epitaxial layer may extend along the top surface of the field insulation layer, and the outer circumferential surface of the first epitaxial layer may not extend along the top surface of the field insulation layer.

Embodiments may be realized by providing a semiconductor device, including a substrate; fin patterns on the substrate; a field insulation layer between the fin patterns; and a contact overlapping and contacting at least some of the fin patterns and at least some of the field insulation layer between the fin patterns, top surfaces of the fin patterns overlapped by the contact being upwardly convex, and top surfaces of the field insulation layer overlapped by the contact being downwardly convex.

The semiconductor device may further include an additional contact, each of the contact and additional contact overlapping at least some of the fin patterns and at least some of the field insulation layer between the fin patterns. Top surfaces of the fin patterns overlapped by each of the contacts may be upwardly convex, and top surfaces of the field insulation layer overlapped by each of the contacts may be downwardly convex.

The semiconductor device may further include a gate electrode between the contacts.

The gate electrode may extend in a direction different from a direction in which the fin patterns extend.

The gate electrode may intersect the fin patterns.

### BRIEF DESCRIPTION OF THE DRAWINGS

Features will become apparent to those of skill in the art by describing in detail exemplary embodiments with reference to the attached drawings in which:

FIG. 1 illustrates a layout view of a semiconductor device according to an embodiment;

FIG. 2 illustrates a cross-sectional view taken along the line A-A of FIG. 1;

FIG. 3 illustrates a cross-sectional view taken along the line B-B of FIG. 1;

FIG. 4 illustrates an enlarged view of a portion ‘O’ of FIG. 3;

FIG. 5A illustrates a cross-sectional view taken along the line C-C of FIG. 1;

FIG. 5B illustrates a diagram of a modified example of the semiconductor device according to the embodiment illustrated in FIG. 1;

FIG. 6 illustrates a diagram of a semiconductor device according to an embodiment;

FIG. 7 illustrates an enlarged view of a portion ‘P’ of FIG. 6;

FIG. 8 illustrates a layout view of a semiconductor device according to an embodiment;

FIG. 9 illustrates a layout view of a semiconductor device according to an embodiment;

FIG. 10 illustrates a cross-sectional view taken along the line B-B of FIG. 9;

FIG. 11 illustrates a layout view of a semiconductor device according to an embodiment;

FIG. 12 illustrates a cross-sectional view taken along lines B-B, D-D and F-F of FIG. 11;

FIG. 13 illustrates a cross-sectional view taken along lines C-C, E-E and G-G of FIG. 11;

FIGS. 14 and 15 illustrate diagrams of a semiconductor device according to an embodiment;

FIG. 16 illustrates a block diagram of a system on chip (SoC) system including semiconductor devices according to embodiments;

FIG. 17 illustrates a block diagram of an electronic system including semiconductor devices according to embodiments; and

FIGS. 18 to 20 illustrate exemplary semiconductor systems to which semiconductor devices according to some embodiments may be applied.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

It will be understood that when an element or layer is referred to as being “connected to,” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present. As used herein, the term “and/or” includes any and all combinations of one or more of the associated listed items.

It will also be understood that when a layer is referred to as being “on” another layer or substrate, it can be directly on the other layer or substrate, or intervening layers may also be present. In contrast, when an element is referred to as being “directly on” another element, there are no intervening elements present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present.

It will be understood that, although the terms first, second, etc., may be used herein to describe various elements, these elements should not be limited by these terms. These terms are only used to distinguish one element from another element. Thus, for example, a first element, a first component or a first section discussed below could be termed a second element, a second component or a second section.

The use of the terms “a” and “an” and “the” and similar referents (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of skill in the art. It is noted that the use of any and all examples, or exemplary terms provided herein is intended merely to better illuminate and is not a limitation on scope unless otherwise specified. Further, unless defined otherwise, all terms defined in generally used dictionaries may not be overly interpreted.

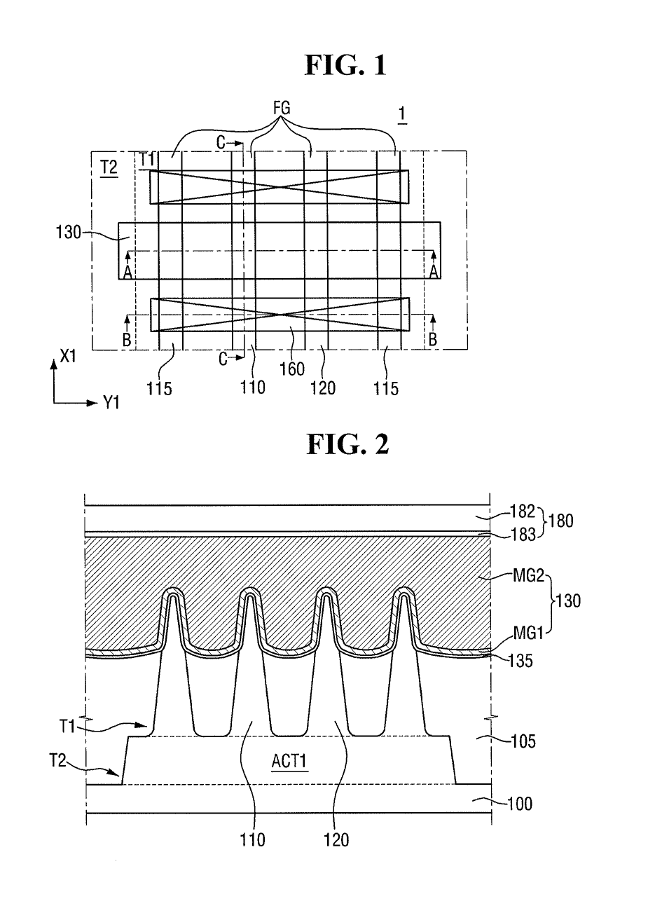

Hereinafter, a semiconductor device according to an embodiment will now be described with reference to FIGS. 1 to 5A.

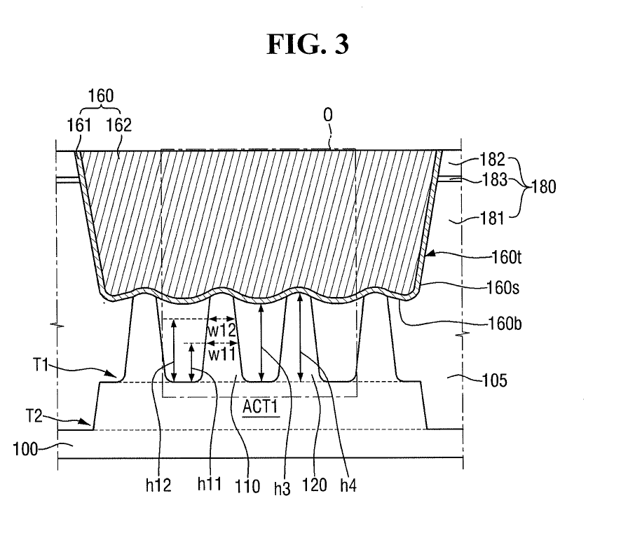

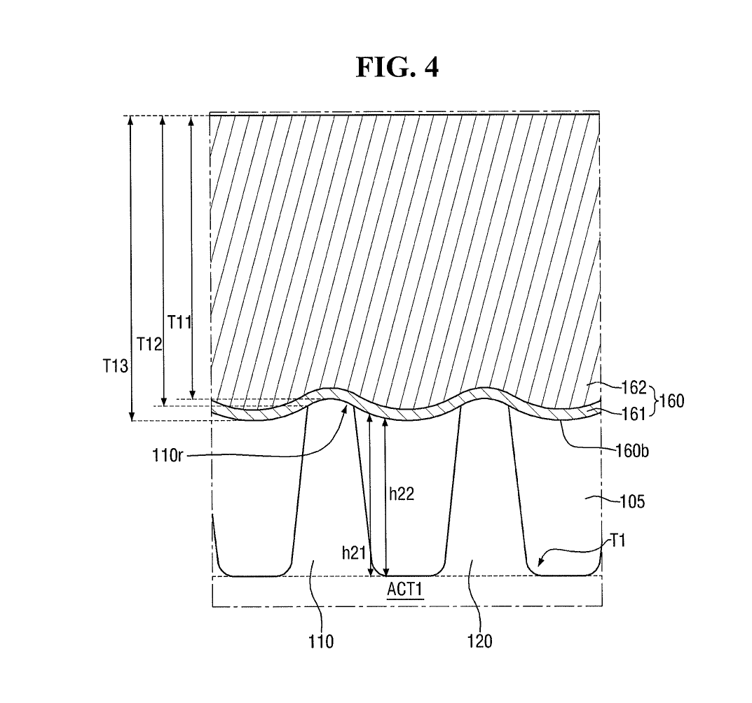

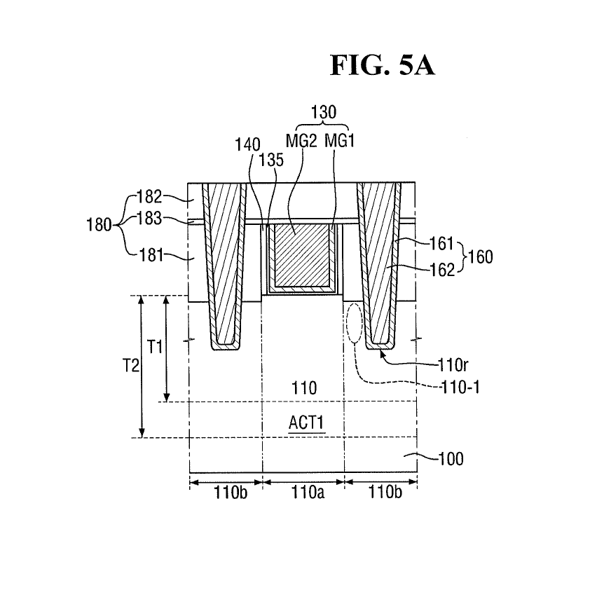

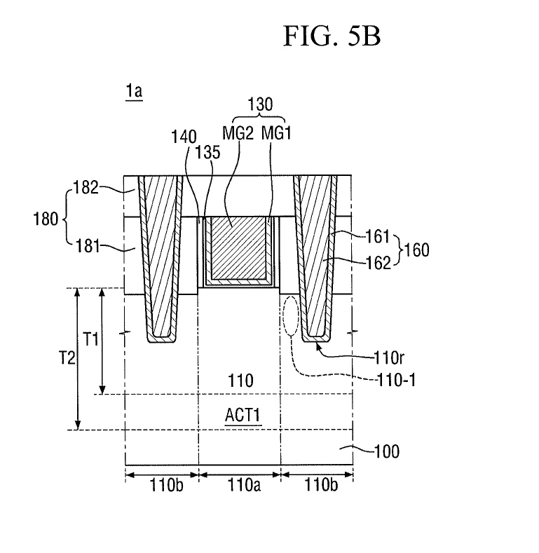

FIG. 1 illustrates a layout view of a semiconductor device according to an embodiment, FIG. 2 illustrates a cross-sectional view taken along the line A-A of FIG. 1, FIG. 3 illustrates a cross-sectional view taken along the line B-B of FIG. 1, FIG. 4 illustrates an enlarged view of a portion ‘O’ of FIG. 3, and FIG. 5A illustrates a cross-sectional view taken along the line C-C of FIG. 1.

Referring to FIGS. 1 to 5A, the semiconductor device 1 according to an embodiment may include a fin type pattern group FG, a first gate electrode 130 and a first contact 160.

The substrate 100 may be a bulk silicon substrate or a silicon on insulator (SOI). In an embodiment, the substrate 100 may be a silicon substrate or a substrate including other materials, such as silicon germanium, indium antimonide, lead telluride, lead telluride, indium arsenide, indium phosphide, gallium arsenide, or gallium antimonide. In an embodiment, the substrate 100 may be an epitaxial layer formed on a base substrate.

The fin type pattern group FG may be formed in a first active region ACT1 of the substrate 100. The fin type pattern group FG may be formed to protrude from the substrate 100, for example, from the first active region ACT1.

The term “fin type pattern group” used herein may mean fin type patterns intersecting one gate electrode. For example, the fin type pattern group FG may be a set of fin type patterns intersecting the first gate electrode 130.

The fin type pattern group FG may include a plurality of fin type patterns extending in a first direction X1. The fin type patterns included in the fin type pattern group FG may extend in the first direction X1. The fin type patterns included in the fin type pattern group FG may also extend in a second direction Y1.

The fin type pattern group FG may include a first fin type pattern 110 and a second fin type pattern 120. The first fin type pattern 110 and the second fin type pattern 120 may be closest to each other. The expression “being closest” used herein may mean that an additional fin type pattern is not disposed between the first fin type pattern 110 and the second fin type pattern 120.

The fin type pattern group FG may further include outermost fin type patterns 115. The outermost fin type patterns 115 may mean fin type patterns disposed at the outermost part of the fin type pattern group FG. For example, the fin type pattern group FG may not be positioned at one side of each of the outermost fin type patterns 115 in the second direction Y1 but the fin type patterns included in the fin type pattern group FG may be positioned at the other side of each of the outermost fin type patterns 115.

As shown, the outermost fin type patterns 115 may include fin type patterns formed at the outermost part of the first active region ACT1.

In FIG. 1, the fin type pattern group FG including four fin type patterns is illustrated, which is provided only for the sake of convenient explanation. In an embodiment, one of the first fin type pattern 110 and the second fin type pattern 120 may be the outermost fin type pattern and both of the first fin type pattern 110 and the second fin type pattern 120 may be the outermost fin type patterns.

The fin type pattern group FG may be a portion of the substrate 100 and may include an epitaxial layer grown from the substrate 100. The respective fin type patterns included in the fin type pattern group FG may include the same material.

The fin type pattern group FG may include, for example, a silicon element semiconductor, such as silicon or germanium. The fin type pattern group FG may include a compound semiconductor, for example, a group IV-IV compound semiconductor or a group III-V compound semiconductor.

The fin type pattern group FG may include, for example, a group IV-IV compound semiconductor, such as a binary compound or a ternary compound including two or more of carbon (C), silicon (Si), germanium (Ge), or tin (Sn) or a compound doped with a IV group element.

The fin type pattern group FG may include, for example, a group III-V compound semiconductor, such as a binary compound, a ternary compound or a quaternary compound, prepared by combining one or more group III element of aluminum (Al), gallium (Ga), or indium (In) with one or more group V element of phosphorus (P), arsenic (As), or antimony (Sb).

In the following description, it is assumed that fin type patterns 110, 115 and 120 included in the fin type pattern group FG include silicon (Si).

In FIG. 5A, the first fin type pattern 110 may include, for example, a first part 110a and a second part 110b. The second part 110b of the first fin type pattern 110 may be disposed at opposite sides of the first part 110a of the first fin type pattern 110 in the first direction X1. Like the first fin type pattern 110, the second fin type pattern 120 may include a first part and a second part.

The fin type patterns 110, 115 and 120 included in the fin type pattern group FG may be defined by a first trench T1 having a first depth and the first active region ACT1 may be defined by a second trench T2 having a second depth greater than the first depth. The first trench T1 may be a shallow trench and the second trench T2 may be a deep trench.

The first trench T1 may be formed at opposite sides of the respective fin type patterns included in the fin type pattern group FG. For example, the first trench T1 may be formed at opposite sides of the first fin type pattern 110 and opposite sides of the second fin type pattern 120.

The first trench T1 separating the first fin type pattern 110 and the second fin type pattern 120 from each other may lengthwise extend in the first direction X1 together with the first fin type pattern 110 and the second fin type pattern 120.

The second trench T2 may be formed at opposite sides of the fin type pattern group FG. The second trench T2 may be formed at one side of each of the outermost fin type patterns 115 among the fin type patterns included in the fin type pattern group FG.

The first trench T1 and the second trench T2 formed at one side of each of the outermost fin type patterns 115 may be disposed to be immediately adjacent to each other. The expression “be immediately adjacent to each other” used herein may mean that another trench having a first depth (that is, shallow trench) is not disposed between the first trench T1 and the second trench T2.

The field insulation layer 105 may be formed on the substrate 100. The field insulation layer 105 may be formed to fill a portion of the first trench T1 and a portion of the second trench T2. The field insulation layer 105 may include, for example, an oxide layer, a nitride layer or a combination thereof.

The field insulation layer 105 may make contact with some of the fin type patterns included in the fin type pattern group FG. At least some of the fin type patterns 110, 115 and 120 included in the fin type pattern group FG may protrude above a top surface of the field insulation layer 105.

The first gate electrode 130 may extend in the second direction Y1 on the fin type pattern group FG. The first gate electrode 130 may entirely intersect the fin type pattern group FG. The first gate electrode 130 may intersect the first fin type pattern 110, the second fin type pattern 120 and the outermost fin type patterns 115.

The first gate electrode 130 may be formed on the field insulation layer 105. For example, the first gate electrode 130 may be formed on the first part 110a of the first fin type pattern 110.

The first gate electrode 130 may include first and second metal layers MG1 and MG2. As shown, the first gate electrode 130 may include two or more metal layers MG1 and MG2 stacked one on another. The first metal layer MG1 may control a work function of a transistor, and the second metal layer MG2 may fill a space formed by the first metal layer MG1. The first metal layer MG1 may include, for example, one or more of TiN, WN, TiAl, TiAlN, TiAlC, TaN, TiC, TaC, TaCN, or TaSiN. The second metal layer MG2 may include, for example, one or more of W, Al, Cu, Co, Ti, Ta, poly-Si, SiGe or metal alloys.

The first gate electrode 130 may be formed by, for example, a replacement process (or a gate last process).

The first gate insulation layer 135 may be formed between the fin type pattern group FG and the first gate electrode 130. The first gate insulation layer 135 may be formed between the first fin type pattern 110 and the first gate electrode 130, between the second fin type pattern 120 and the first gate electrode 130 and between the outermost fin type patterns 115 and the first gate electrode 130.

The first gate insulation layer 135 may be formed along a profile of the fin type pattern group FG protruding above the field insulation layer 105, for example, a profile of the first fin type pattern 110 and a profile of the second fin type pattern 120. The first gate insulation layer 135 may also be formed between the first gate electrode 130 and the field insulation layer 105.

The first gate insulation layer 135 may include, for example, silicon oxide, silicon oxynitride, silicon nitride, or a high-k material. The high-k material may include, for example, one or more of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The first spacer 140 may be formed on sidewalls of the first gate electrode 130 extending in the second direction Y1. The first spacer 140 may include, for example, one or more of silicon nitride (SiN), silicon oxynitride (SiON), silicon oxide (SiO₂), or silicon oxycarbonitride (SiOCN).

An impurity region may be formed at opposite sides of the first gate electrode 130. The impurity region may be formed in the fin type patterns 110, 115 and 120 included in the fin type pattern group FG.

The interlayer dielectric film 180 may cover the fin type pattern group FG. The interlayer dielectric film 180 may cover the first gate electrode 130. The interlayer dielectric film 180 may be formed on the substrate 100, for example, the field insulation layer 105.

The lower interlayer dielectric film 181 may surround the sidewalls of the first gate electrode 130. An interlayer liner film 183 and an upper interlayer dielectric film 182 may be formed on the first gate electrode 130. The interlayer liner film 183 may be formed along a top surface of the first gate electrode 130.

The interlayer dielectric film 180 may include the lower interlayer dielectric film 181, the interlayer liner film 183 and the upper interlayer dielectric film 182, which are sequentially formed on the field insulation layer 105. The lower interlayer dielectric film 181 and the upper interlayer dielectric film 182 may be divided by, for example, the interlayer liner film 183.

Each of the lower interlayer dielectric film 181 and the upper interlayer dielectric film may include, for example, one or more of a silicon oxide layer, a silicon nitride layer, a silicon oxynitride layer, or a low-k material having a lower dielectric constant than silicon oxide. The low-k material may include, for example, flowable oxide (FOX), tonen silazene (TOSZ), undoped silicate glass (USG), borosilica glass (BSG), phosphosilica glass (PSG), borophosphor silica glass (BPSG), plasma enhanced tetraethyl orthosilicate (PETEOS), fluoride silicate glass (FSG), carbon doped silicon oxide (CDO), xerogel, aerogel, amorphous fluorinated carbon, organo silicate glass (OSG), parylene, bis-benzocyclobutenes (BCB), SiLK, polyimide, porous polymeric material, or a combination thereof.

The interlayer liner film 183 may include, for example, different materials from the lower interlayer dielectric film 181 and the upper interlayer dielectric film 182. The interlayer liner film 183 may include, for example, silicon nitride (SiN).

The interlayer dielectric film 180 may include a first contact hole 160t. The first contact hole 160t may extend in the second direction Y1 to be formed on at least one side of the first gate electrode 130.

The first contact hole 160t may be formed on the impurity region disposed at opposite sides of the first gate electrode 130. The first contact hole 160t may be formed to intersect the fin type pattern group FG.

At least one fin type pattern included in the fin type pattern group FG may be exposed by the first contact hole 160t. The field insulation layer 105 may also be exposed by the first contact hole 160t, and a bottom surface of the first contact hole 160t may be defined by a top surface of the at least one fin type pattern included in the fin type pattern group FG and the top surface of the field insulation layer 105.

For example, the bottom surface of the first contact hole 160t defined by the top surface of the first fin type pattern 110 may be a bottom of the first recess 110r formed in the second part 110b of the first fin type pattern 110. The first recess 110r may be part of the first contact hole 160t.

In the following description of the semiconductor device according to the embodiment illustrated in FIG. 1, it is assumed that all of the fin type patterns included in the fin type pattern group FG are exposed by the first contact hole 160t.

As shown, in semiconductor devices according to embodiments, the bottom surface of the first contact hole 160t may be shaped of a wave. For example, the bottom surface of the first contact hole 160t defined by the fin type pattern group FG has a ridge of the wave, and the bottom surface of the first contact hole 160t defined by the top surface of the field insulation layer 105 has a valley of the wave.

The top surface of the fin type pattern group FG defining the bottom surface of the first contact hole 160t and the top surface of the field insulation layer 105 may have curved surfaces.

The first contact 160 may be formed in the interlayer dielectric film 180. The first contact 160 may be formed to fill the first contact hole 160t. The first contact 160 may be formed while passing through the upper interlayer dielectric film 182, the interlayer liner film 183 and the lower interlayer dielectric film 181.

The first contact hole 160t may be formed on at least one side of the first gate electrode 130, and the first contact 160 may be formed on at least one side of the first gate electrode 130, for example, at opposite sides of the first gate electrode 130.

The first contact 160 may be formed on the fin type pattern group FG positioned at one side of the first gate electrode 130. The first contact 160 may extend in the second direction Y1 and may intersect the fin type pattern group FG.

The first contact 160 may include a first barrier layer 161 and a first filling layer 162. The first barrier layer 161 may be formed along the first contact hole 160t formed in the interlayer dielectric film 180.

The first filling layer 162 may fill the first contact hole 160t. The first filling layer 162 may be formed on the first barrier layer 161.

The first barrier layer 161 may include, for example, tantalum (Ta), tantalum nitride (TaN), titanium (Ti), titanium nitride (TiN), ruthenium (Ru), cobalt (Co), nickel (Ni), nickel boride (NiB), or tungsten nitride (WN).

The first filling layer 162 may include, for example, aluminum (Al), tungsten (W), copper (Cu), cobalt (Co), or doped polysilicon.

In the semiconductor device 1 according to the embodiment illustrated in FIG. 1, the first contact 160 may intersect all of the fin type patterns 110, 115 and 120 included in the fin type pattern group FG formed in the first active region ACT1. The number of fin type patterns included in the fin type pattern group FG intersecting with the first gate electrode 130 may equal to the number of fin type patterns included in the fin type pattern group FG intersecting with the first contact 160.

The bottom surface of the first contact hole 160t may be defined by a top surface of at least one fin type pattern included in the fin type pattern group FG and the top surface of the field insulation layer 105, and the first contact 160 may make contact with the field insulation layer 105 and the fin type pattern group FG. For example, the first contact 160 may make contact with the first fin type pattern 110 and the second fin type pattern 120.

In the semiconductor device 1 according to the embodiment illustrated in FIG. 1, the bottom surface (160b) of the first contact 160 may make contact with all of the fin type patterns 110, 115 and 120 included in the fin type pattern group FG.

A bottom surface 160b of the first contact 160 may be continuously formed along the top surface of the fin type pattern group FG and the top surface of the field insulation layer 105, which will now be described, for example, with regard to the first fin type pattern 110 and the second fin type pattern 120 which are closest to each other and the field insulation layer 105 between the first fin type pattern 110 and the second fin type pattern 120.

The bottom surface 160b of the first contact 160 may be continuously formed along the top surface of the first fin type pattern 110, the top surface of the field insulation layer 105 and the top surface of the second fin type pattern 120.

The first contact 160 may make contact with the fin type pattern group FG and semiconductor patterns formed on the fin type pattern group FG may not be formed between the first contact 160 and the fin type pattern group FG. The first contact 160 and the fin type pattern group FG may be formed to make direct contact with each other, and the high-voltage operating stability of the semiconductor device may be improved.

The bottom surface 160b of the first contact 160 may be continuously formed along the top surface of the fin type pattern group FG and the top surface of the field insulation layer 105. The first contact 160 may make contact with the fin type pattern group FG and the field insulation layer 105.

Sidewalls of the first fin type pattern 110 and sidewalls of the second fin type pattern 120 may be entirely surrounded by the field insulation layer 105 at regions where the first fin type pattern 110 and the second fin type pattern 120 overlap with the first contact 160.

The first fin type pattern 110 may be defined by the first trench T1, and slopes of the sidewalls of the first fin type pattern 110 may have the same sign at various points on the sidewalls of the first fin type pattern 110.

A width of the first fin type pattern 110 may be a first width W11 at a first height h11 ranging from a bottom of the first trench T1 and a width of the first fin type pattern 110 may be a second width W12 at a second height h12 ranging from the bottom of the first trench T1. The second height h12 may be greater than the first height h11, and, for example, the width W11 of the first fin type pattern 110 at the first height h11 ranging from the bottom of the first trench T1 may be greater than or equal to the width W12 of the first fin type pattern 110 at the second height h12 ranging from the bottom of the first trench T1.

The bottom surface of the first contact hole 160t may have a wave shape, and the bottom surface 160b of the first contact 160 may be shaped of a wave. For example, the top surface of the first fin type pattern 110 and the top surface of the second fin type pattern 120 overlapping and making contact with the first contact 160 may have curved surfaces, respectively. The top surface of the field insulation layer 105 overlapping and making contact with the first contact 160 may have a curved surface.

The top surface of the first fin type pattern 110 may be upwardly convex at a region where the first fin type pattern 110 overlaps with the first contact 160. The top surface of the field insulation layer 105 may be downwardly convex at a region where the field insulation layer 105 overlaps with the first contact 160.

In the semiconductor device 1 according to embodiment illustrated in FIG. 1, the bottom surface 160b of the first contact 160 making contact with the first fin type pattern 110 and the second fin type pattern 120 may have a ridge of a wave, and the bottom surface 160b of the first contact 160 making contact with the field insulation layer 105 may have a valley of a wave.

The bottom surface 160b of the first contact 160 making contact with the field insulation layer 105 between the first fin type pattern 110 and the second fin type pattern 120 may have a first point and a second point. The first point may be closer to the first fin type pattern 110 than the second point.

A height h21 ranging from the bottom of the first trench T1 to the first point may be greater than a height h22 ranging from the bottom of the first trench T1 to the second point.

An average thickness of the first contact 160 at a region where the first contact 160 overlaps with the top surface of the field insulation layer 105 may be greater than an average thickness of the first contact 160 at a region where the first contact 160 overlaps with the top surface of the fin type pattern group FG.

For example, a first average thickness of the first contact 160 at a region where the first contact 160 overlaps with the top surface of the first fin type pattern 110 may be equal to a mean of a thickness t11 of the first contact 160 at a topmost part of the top surface of the first fin type pattern 110 and a thickness t12 of the first contact 160 at a portion where the top surface of the first fin type pattern 110 and the field insulation layer 105 make contact with each other.

A second average thickness of the first contact 160 at the region where the first contact 160 overlaps with the top surface of the field insulation layer 105 may be equal to a mean of a thickness t12 of the first contact 160 at the portion where the top surface of the first fin type pattern 110 and the field insulation layer 105 make contact with each other and a thickness t13 of the first contact 160 at a bottommost part of the top surface of the field insulation layer 105.

A height h3 ranging from the bottom of the first trench T1 to the bottommost part of the field insulation layer 105 at a region overlapping the first contact 160 may be smaller than a height h4 ranging from the bottom of the first trench T1 to the topmost part of the top surface of the fin type pattern group FG.

The bottom surface of the first contact hole 160t defined by the top surface of the first fin type pattern 110 may correspond to a bottom surface of a first recess 110r formed in the second part 110b of the first fin type pattern 110, and the first contact 160 may be formed by filling the first recess 110r formed in the second part 110b of the first fin type pattern 110. A portion of the first contact 160 filling the first recess 110r may make contact with the first fin type pattern 110.

The first recess 110r may be formed in the second part 105b second part 105b of the first fin type pattern 105 protruding above the top surface of the field insulation layer 105, and the first contact 160 may be formed to pass through the first fin type pattern 110 protruding above the top surface of the field insulation layer 105. The first contact 160 may be formed to pass through the second part 110b of the first fin type pattern 110.

A width of the first contact 160 in a first direction X1 may be smaller than a width of the second part 110b of the first fin type pattern 110 in the first direction X1, and a semiconductor region 110-1 that is part of the second part 110b of the first fin type pattern 110 may be interposed between the first spacer 140 and the first contact 160.

FIG. 5A illustrates that a top surface of the second part 110b of the first fin type pattern 110 positioned between the first spacer 140 and the first contact 160 is, for example, recessed from the top surface of the first part 110a of the first fin type pattern 110 overlapping the first gate electrode 130, which is illustrated only for the sake of convenient explanation.

FIG. 5B illustrates a diagram of a modified example of the semiconductor device according to embodiment illustrated in FIG. 1. FIG. 5B may be a cross-sectional view taken along the line C-C of FIG. 1.

Referring to FIG. 5B, in the modified example of the semiconductor device according to the embodiment illustrated in FIG. 1, an interlayer dielectric film 180 may not include an interlayer liner film 183.

An upper interlayer dielectric film 182 is formed on a lower interlayer dielectric film 181, so that the lower interlayer dielectric film 181 and the upper interlayer dielectric film 182 may make contact with each other.

The lower interlayer dielectric film 181 and the upper interlayer dielectric film 182 may be defined according to whether they are deposited before forming a first gate electrode 130, for example.

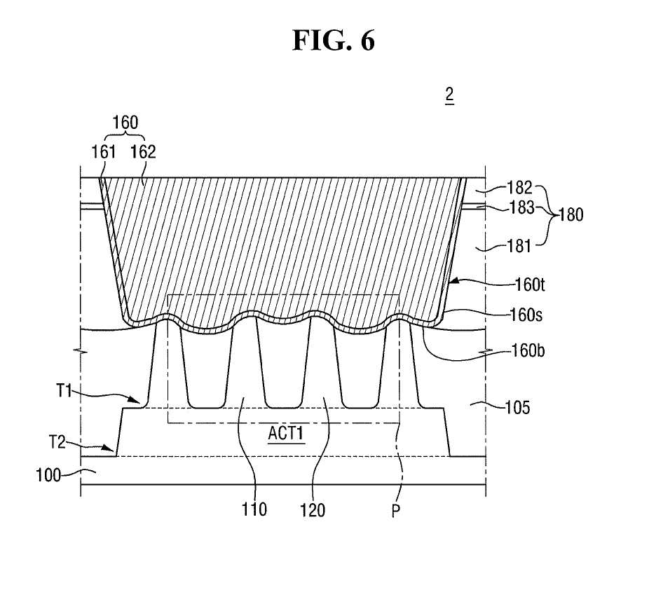

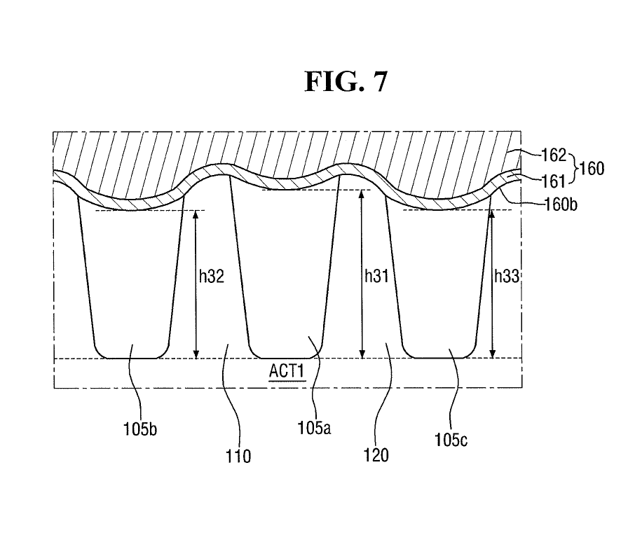

FIG. 6 illustrates a diagram of a semiconductor device according to an embodiment and FIG. 7 illustrates an enlarged view of a portion ‘P’ of FIG. 6. For the sake of convenient explanation, the following description of the semiconductor device according to the embodiment illustrated in FIG. 6 will focus on differences from the semiconductor device according to an embodiment illustrated in FIGS. 1 to 5A.

Referring to FIGS. 6 and 7, in the semiconductor device 2 according to an embodiment, a field insulation layer 105 formed in a first trench T1 defining fin type patterns 110, 115 and 120 included in a fin type pattern group FG may have periodically increasing or decreasing heights.

The field insulation layer 105 may include a first part 105a, a second part 105b and a third part 105c.

The first part 105a of the field insulation layer 105 may be disposed between the first fin type pattern 110 and the second fin type pattern 120. The first part 105a of the field insulation layer 105 may make contact with both of sidewalls of the first fin type pattern 110 and sidewalls of the second fin type pattern 120.

The second part 105b of the field insulation layer 105 may be disposed to correspond to the first part 105a of the field insulation layer 105 in view of the first fin type pattern 110. The third part 105c of the field insulation layer 105 may be disposed to correspond to the first part 105a of the field insulation layer 105 in view of the second fin type pattern 120. The second part 105b of the field insulation layer 105 and the third part 105c of the field insulation layer 105 may not make contact with both of the sidewalls of the first fin type pattern 110 and the sidewalls of the second fin type pattern 120.

The second part 105b of the field insulation layer 105 may make contact with the sidewalls of the first fin type pattern 110 but may not make contact with the sidewalls of the second fin type pattern 120. The third part 105c of the field insulation layer 105 may make contact with the sidewalls of the second fin type pattern 120 but may not make contact with the sidewalls of the first fin type pattern 110.

A height h31 ranging from a bottom of the first trench T1 to a bottommost part of the first part 105a of the top surface of the field insulation layer 105 may be different from a height h32 ranging from the bottom of the first trench T1 to a bottommost part of the second part 105b of the top surface of the field insulation layer 105 and a height h33 ranging from the bottom of the first trench T1 to a bottommost part of the third part 105c of the top surface of the field insulation layer 105.

In the semiconductor device 2 according to the embodiment illustrated in FIG. 6, the height h31 ranging from the bottom of the first trench T1 to the bottommost part of the first part 105a of the top surface of the field insulation layer 105 may be greater than the height h32 ranging from the bottom of the first trench T1 to the bottommost part of the second part 105b of the top surface of the field insulation layer 105 and the height h33 ranging from the bottom of the first trench T1 to the bottommost part of the third part 105c of the top surface of the field insulation layer 105.

The bottom surface 160b of the first contact 160 extending along a top surface of the field insulation layer 105 may also have periodically increasing or decreasing heights in view of the bottom of the first trench T1.

FIG. 7 illustrates that the height h32 ranging from the bottom of the first trench T1 to the bottommost part of the second part 105b of the top surface of the field insulation layer 105 is, for example, substantially equal to the height h33 ranging from the bottom of the first trench T1 to the bottommost part of the third part 105c of the top surface of the field insulation layer 105, which is illustrated only for the sake of convenient explanation.

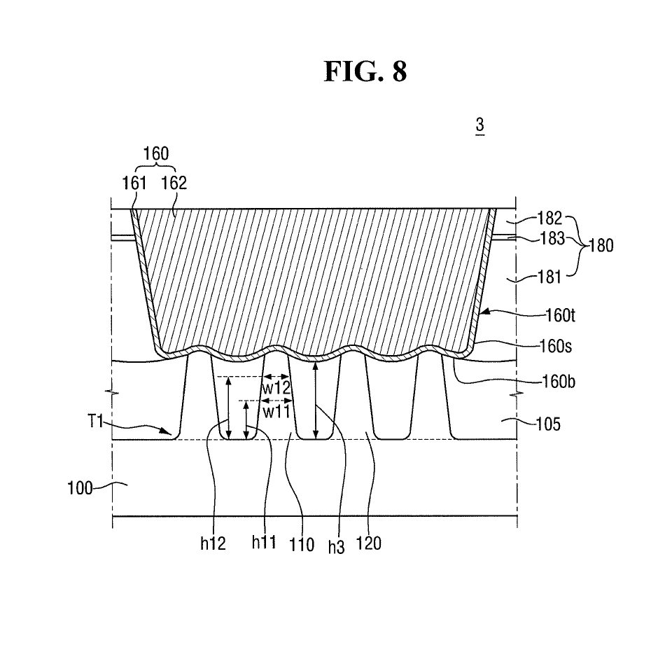

FIG. 8 illustrates a layout view of a semiconductor device according to an embodiment. For the sake of convenient explanation, the following description of the semiconductor device according to the embodiment illustrated in FIG. 8 will focus on differences from the semiconductor device according to the first embodiment illustrated in FIGS. 1 to 5A.

Referring to FIG. 8, in the semiconductor device 3 according to an embodiment, a second trench (T2 of FIG. 2) deeper than a first trench T1 may not be formed at opposite sides of a fin type pattern group FG.

In an embodiment, fin type patterns 110, 115 and 120 included in the fin type pattern group FG may be defined and separated from each other by the first trench T1.

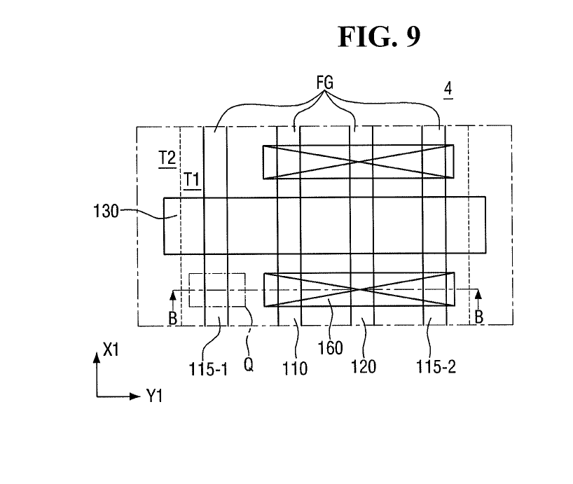

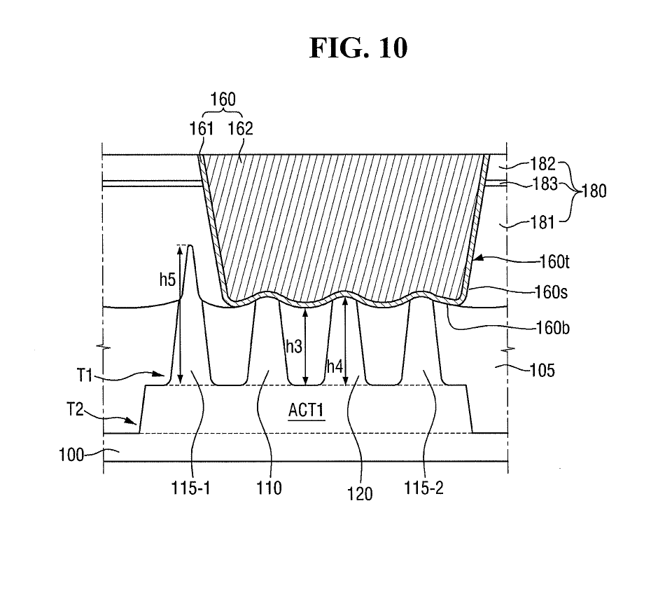

FIG. 9 illustrates a layout view of a semiconductor device according to an embodiment and FIG. 10 illustrates a cross-sectional view taken along the line B-B of FIG. 9. For the sake of convenient explanation, the following description of the semiconductor device according to the embodiment illustrated in FIG. 9 will focus on differences from the semiconductor device according to the first embodiment illustrated in FIGS. 1 to 5A.

Referring to FIGS. 9 and 10, in the semiconductor device 4 according to an embodiment, a fin type pattern group FG may include a first outermost fin type pattern 115-1 and a second outermost fin type pattern 115-2. The first contact 160 may not intersect at least one of the outermost fin type patterns 115-1 and 115-2.

The number of fin type patterns included in the fin type pattern group FG intersecting a first gate electrode 130 may be different from the number of fin type patterns included in the fin type pattern group FG intersecting a first contact 160.

A first outermost fin type pattern 115-1 not intersecting the first contact 160 and a second outermost fin type pattern 115-2 intersecting the first contact 160 are illustrated, for example, in FIG. 9. In an embodiment, the second outermost fin type pattern 115-2 may not intersect the first contact 160, either.

The bottom surface 160b of the first contact 160 may not make contact with the first outermost fin type pattern 115-1. Sidewalls 160s of the first contact 160 may not make contact with the first outermost fin type pattern 115-1. The sidewalls 160s of the first contact 160 may not make contact with the first outermost fin type pattern 115-1 protruding above the top surface of the field insulation layer 105.

FIG. 10 illustrates that the sidewalls 160s of the first contact 160, for example, do not make contact with the first outermost fin type pattern 115-1, which is illustrated only for the sake of convenient explanation. In an embodiment, some portions of the sidewalls 160s of the first contact 160 may make contact with the first outermost fin type pattern 115-1.

The following description will be made on the assumption that the sidewalls 160s of the first contact 160 do not make contact with the first outermost fin type pattern 115-1.

The first fin type pattern 110 and the second fin type pattern 120 may intersect the first contact 160, and each of the first fin type pattern 110 and the second fin type pattern 120 may include a region intersecting the first contact 160. In an embodiment, the first outermost fin type pattern 115-1 may not intersect the first contact 160, and it may not include a region intersecting the first outermost fin type pattern 115-1.

In an embodiment, the first outermost fin type pattern 115-1 may include a region Q intersecting an extension line of the first contact 160 extending in a second direction Y1. At the region Q where the extension line of the first contact 160 extending in a second direction Y1 and the first outermost fin type pattern 115-1 intersect each other, a height ranging from a bottom of a first trench T1 to an uppermost part of the first outermost fin type pattern 115-1 may be a third height h5.

In the semiconductor device 4 according to the embodiment illustrated in FIG. 9, the third height h5 ranging from the bottom of the first trench T1 to the uppermost part of the first outermost fin type pattern 115-1 may be greater than a height h4 ranging from the bottom of the first trench T1 to an uppermost part of the second fin type pattern 120 at a region where the second fin type pattern 120 and the first contact 160 intersect each other.

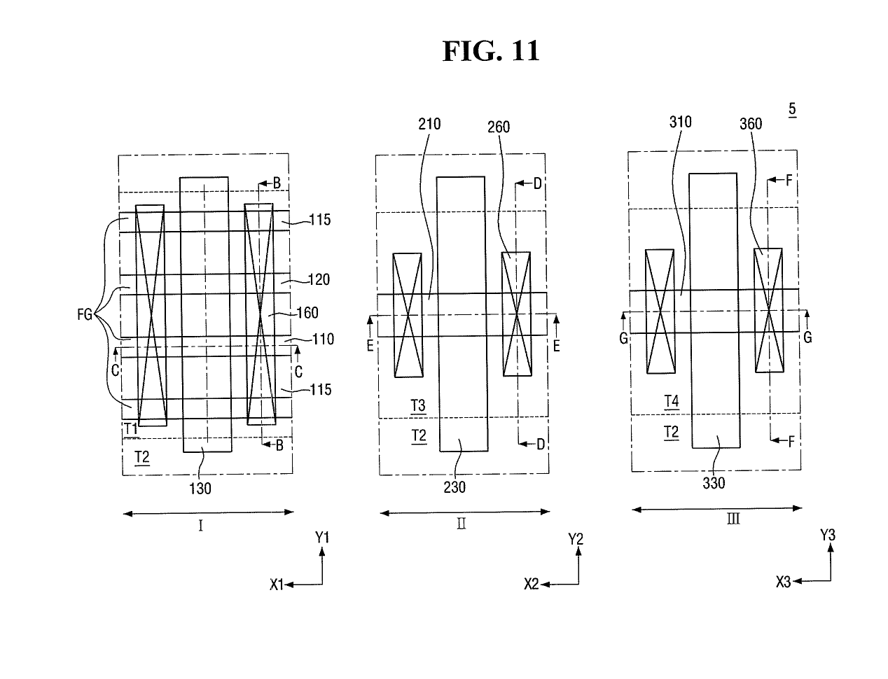

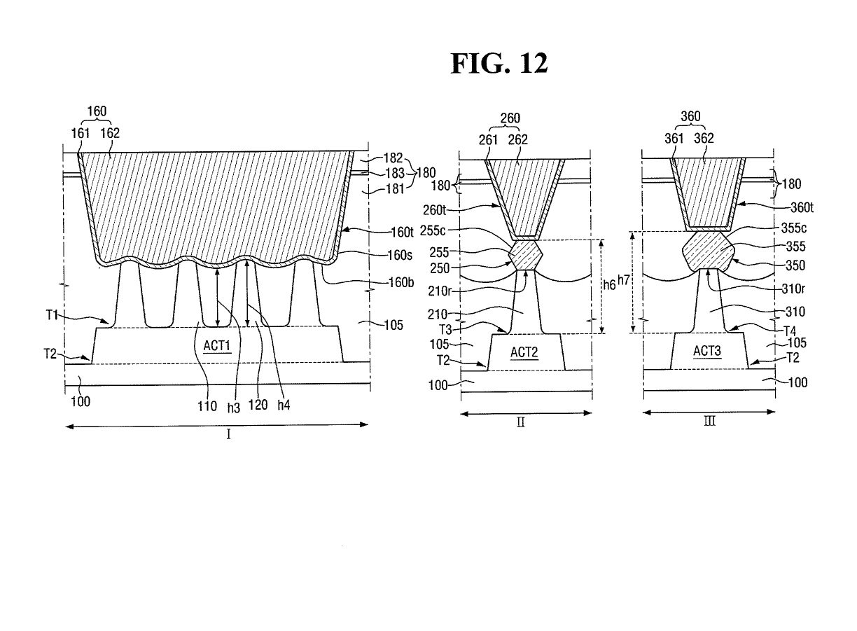

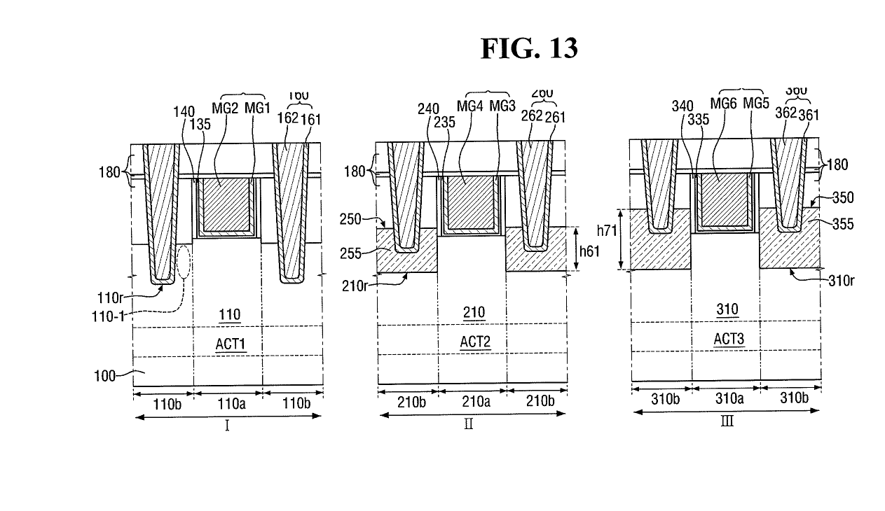

FIG. 11 illustrates a layout view of a semiconductor device according to an embodiment, FIG. 12 illustrates a cross-sectional view taken along lines B-B, D-D and F-F of FIG. 11 and FIG. 13 illustrates a cross-sectional view taken along lines C-CE-E and G-G of FIG. 11.

The layout view and cross-sectional views illustrated in first regions I of FIGS. 11 to 13 are substantially the same as those illustrated in FIGS. 1, 3 and 5A, and repeated descriptions thereof will not be given.

Referring to FIGS. 11 to 13, the semiconductor device 5 according to an embodiment may include a first active region ACT1, a second active region ACT2, a third active region ACT3, a fin type pattern group FG, a first gate electrode 130, a first contact 160, a third fin type pattern 210, a second gate electrode 230, a second contact 260, a fourth fin type pattern 310, a third gate electrode, and a third contact 360.

A substrate 100 may include the first active region ACT1, the second active region ACT2 and the third active region ACT3, which are separated from one another. The first to third active regions ACT1, ACT2 and ACT3 may be defined by a second trench T2 having a second depth.

In the semiconductor device 5 according to the embodiment illustrated in FIG. 11, the second active region ACT2 may be a PMOS region and the third active region ACT3 may be an NMOS region. In the semiconductor device 5 according to the embodiment illustrated in FIG. 11, the second active region ACT2 may be a PMOS region and the third active region ACT3 may be an NMOS region.

The third fin type pattern 210 may be formed in the second active region ACT2. The third fin type pattern 210 may extend lengthwise along a third direction X2. The third fin type pattern 210 may be defined by a third trench T3 having a third depth smaller than the second depth.

The fourth fin type pattern 310 may be formed in the third active region ACT3. The fourth fin type pattern 310 may extend lengthwise along a fifth direction X3. The fourth fin type pattern 310 may be defined by a fourth trench T4 having a fourth depth smaller than the second depth.

The first trench T1, the third trench T3 and the fourth trench T4 may be formed at the same time. The first trench T1, the third trench T3 and the fourth trench T4 may have the same depth.

As illustrated in FIG. 11, a third fin type pattern 210 and a fourth fin type pattern 310, each formed of a single fin (that is, single fin structure), may be formed in the second active region ACT2 and the third active region ACT3, respectively. The semiconductor device 5 according to the embodiment illustrated in FIG. 11 may be a single fin type transistor using the third fin type pattern 310 or the fourth fin type pattern 310.

Unlike in the illustrated embodiment, two or more fin type patterns (that is, a dual fin structure or a multi fin structure) may be formed in the second active region ACT2 and/or the third active region ACT3.

Descriptions of the third fin type pattern 210 and the fourth fin type pattern 310 may be substantially the same as those of the fin type patterns included in the fin type pattern group FG, and repeated descriptions thereof will not be given.

The following description will be made on the assumption that each of the third fin type pattern 210 and the fourth fin type pattern 310 includes silicon (Si).

A field insulation layer 105 may be formed to fill a portion of the first trench T1, a portion of the second trench T2, a portion of the third trench T3 and a portion of the fourth trench T4.

The second gate electrode 230 may extend in a fourth direction Y2 to be formed on the third fin type pattern 210. The third gate electrode may extend in a sixth direction Y3 to be formed on the fourth fin type pattern 310.

The second gate electrode 230 may include metal layers MG3 and MG4 and the third gate electrode may include metal layers MG5 and MG6. Descriptions of the second gate electrode 230 and the third gate electrode may be substantially the same as the description of the first gate electrode 130.

The second gate insulation layer 235 may be formed between the third fin type pattern 210 and the second gate electrode 230 and the third gate insulation layer 335 may be formed between the fourth fin type pattern 310 and the third gate electrode.

The second spacer 240 may be formed on sidewalls of the second gate electrode 230 and the third spacer 340 may be formed on sidewalls of the third gate electrode.

The first source/drain 250 may be formed at opposite sides of the second gate electrode 230. The first source/drain 250 may be formed on a second part 210b of the third fin type pattern 210.

In the semiconductor device 5 according to the embodiment illustrated in FIG. 11, the first source/drain 250 may include a first epitaxial layer 255 filling a second recess 210r formed on the second part 210b of the third fin type pattern 210. The first source/drain 250 may include a first epitaxial layer 255 formed on a top surface of the second part 210b of the third fin type pattern 210.

An outer circumferential surface 255c of the first epitaxial layer 255 may make contact with the field insulation layer 105 but may not include a portion extending along a top surface of the field insulation layer 105.

The second active region ACT2 may be a PMOS region, and the first epitaxial layer 155 may include a compressive stress material. For example, the compressive stress may include a material having a larger lattice constant than Si, e.g., SiGe. The compressive stress material may improve the mobility of carriers of a channel region by applying compressive stress to the third fin type pattern 210 (e.g., a first part 210a of the third fin type pattern 210).

The second source/drain 350 may be formed at opposite sides of the third gate electrode. The second source/drain 350 may be formed on the second part 310b of the fourth fin type pattern 310.

In the semiconductor device 5 according to the embodiment illustrated in FIG. 11, the second source/drain 350 may include a second epitaxial layer 355 filling a third recess 310r formed on the second part 310b of the fourth fin type pattern 310. The second source/drain 350 may include the second epitaxial layer 355 formed on the top surface of the second part 310b of the fourth fin type pattern 310.

The outer circumferential surface 355c of the second epitaxial layer 355 may make contact with the field insulation layer 105 and may include a portion extending along the top surface of the field insulation layer 105.

The third active region ACT3 may be an NMOS region, and the second epitaxial layer 355 may include the same material as the fourth fin type pattern 310 or a tensile stress material. For example, when the fourth fin type pattern 310 includes Si, the second epitaxial layer 355 includes Si or a material having a smaller lattice constant than Si (e.g., silicon carbide).

In the semiconductor device 5 according to the embodiment illustrated in FIG. 11, a height h61 ranging from a bottom of the second recess 210r to a topmost part of the first epitaxial layer 255 may be smaller than a height h71 ranging from a bottom of the third recess 310r to a topmost part of the second epitaxial layer 355.

The interlayer dielectric film 180 may include a second contact hole 260t and a third contact hole 360t. The second contact hole 260t may expose the first source/drain 250 and the third contact hole 360t may expose the second source/drain 350. The second contact hole 260t and the third contact hole 360t may not expose the field insulation layer 105.

The second contact 260 may be formed in the interlayer dielectric film 180 and may be formed by filling the second contact hole 260t. The second contact 260 may be formed on the first source/drain 250. The second contact hole 260t may not expose the field insulation layer 105, and the second contact 260 may not make contact with the field insulation layer 105.

The second contact 260 may include a second barrier layer 261 and a second filling layer 262. The second barrier layer 261 may be formed along the second contact hole 260t formed in the interlayer dielectric film 180. The second filling layer 262 may fill the second contact hole 260t having the second barrier layer 261 formed therein. The second filling layer 262 may be formed on the second barrier layer 261.

The third contact 360 may be formed in the interlayer dielectric film 180 and may be formed by filling the third contact hole 360t. The third contact 360 may be formed on the second source/drain 350. The third contact hole 360t may not expose the field insulation layer 105, and the third contact 360 may not make contact with the field insulation layer 105.

The third contact 360 may include a third barrier layer 361 and a third filling layer 362. The third barrier layer 361 may be formed along the third contact hole 360t formed in the interlayer dielectric film 180. The third filling layer 362 may fill the third contact hole 360t having the third barrier layer 361 formed therein. The third filling layer 362 may be formed on the third barrier layer 261.

In the semiconductor device 5 according to the embodiment illustrated in FIG. 11, a height h3 ranging from a bottom of the first trench T1 to a bottommost part of the first contact 160 may be smaller than a height h6 ranging from a bottom of the third trench T3 to a bottommost part of the second contact 260 and a height h7 ranging from a bottom of the fourth trench T4 to a bottommost part of the third contact 360.

In the semiconductor device 5 according to the embodiment illustrated in FIG. 11, the height h6 ranging from the bottom of the third trench T3 to the bottommost part of the second contact 260 and the height h7 ranging from the bottom of the fourth trench T4 to the bottommost part of the third contact 360.

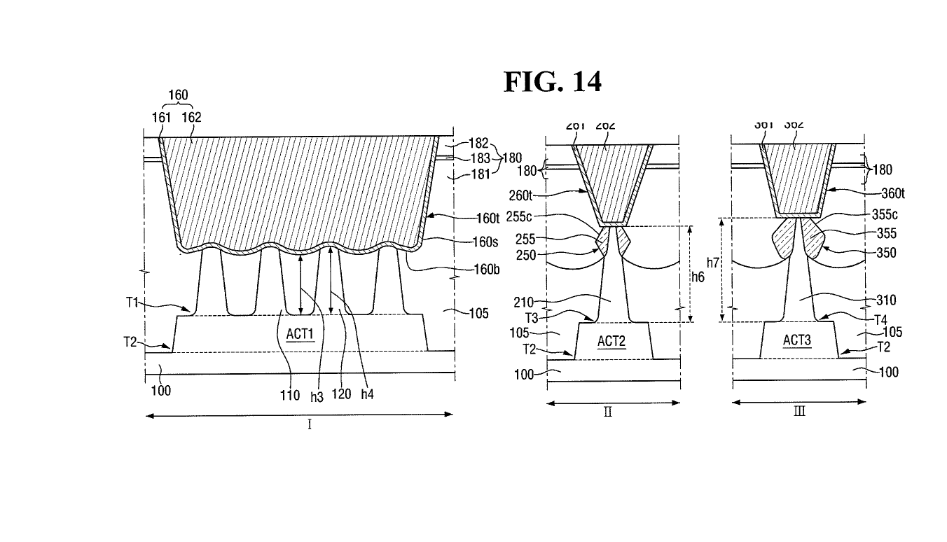

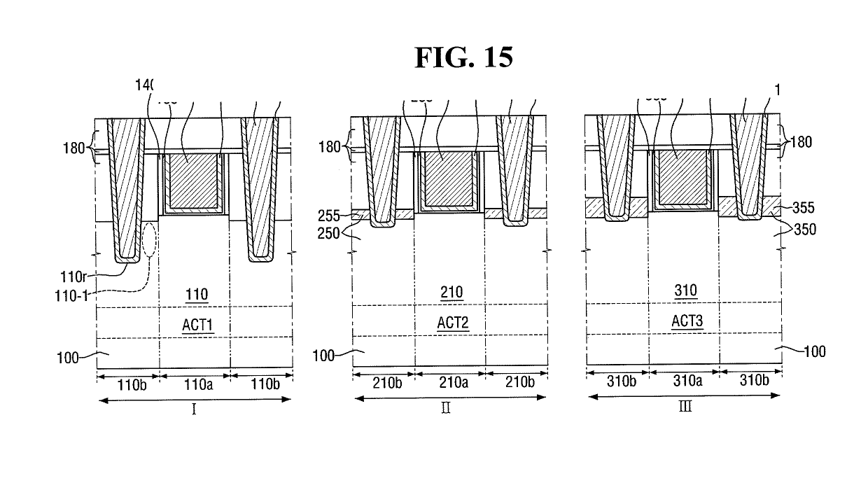

FIGS. 14 and 15 illustrate diagrams of a semiconductor device according to an embodiment. For the sake of convenient explanation, the following description of the semiconductor device according to the embodiment illustrated in FIG. 14 will focus on differences from the semiconductor device according to an embodiment illustrated in FIGS. 11 to 13.

Referring to FIGS. 14 and 15, in the semiconductor device 6 according to an embodiment, a first source/drain 250 may include a first epitaxial layer 255 formed along a profile of a third fin type pattern 210 protruding above a top surface of the field insulation layer 105.

A second source/drain 350 may include a second epitaxial layer 355 formed along a profile of a fourth fin type pattern 310 protruding above the top surface of the field insulation layer 105.

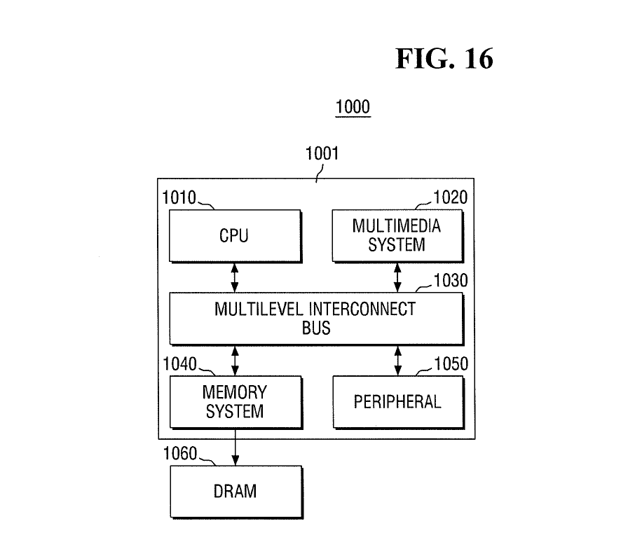

FIG. 16 illustrates a block diagram of a system on chip (SoC) system including semiconductor devices according to embodiments.

Referring to FIG. 16, the SoC system 1000 may include an application processor 1001 and a dynamic random access memory (DRAM) 1060.

The application processor 1001 may include a central processing unit (CPU) 1010, a multimedia system 1020, a multilevel interconnect bus 1030, a memory system 1040, and a peripheral circuit (PERIPHERAL) 1050.

The CPU 1010 may execute computations required to drive the SoC system 1000. In some embodiments, the CPU 1010 may be configured by multi-core environments including a plurality of cores.

The multimedia system 1020 may be used when the SoC system 1000 performs various multimedia functions. The multimedia system 1020 may include a 3D engine module, a video codec, a display system, a camera system, and a post-processor.

The multilevel interconnect bus 1030 may be used when the CPU 1010, the multimedia system 1020, the memory system 1040, and the peripheral circuit 1050 perform data communication with each other. In some embodiments, the bus 1030 may have a multi-layer structure. Examples of the multilevel interconnect bus 1030 may include, for example, a multi-layer advanced high-performance bus (AHB) or a multi-layer advanced eXtensible interface (AXI).

The memory system 1040 may provide an environment required for high-speed operation of the application processor 1001 connected to an external memory (for example, DRAM 1060). In some embodiments, the memory system 1040 may include a separate controller (for example, a DRAM controller) for controlling the external memory (for example, DRAM 1060).

The peripheral circuit 1050 may provide environments required for the SoC system 1000 to be smoothly connected to an external device (e.g., a main board), and the peripheral circuit 1050 may include various interfaces to be compatible with the external device connected to the SoC system 1000.

The DRAM 1060 may function as a working memory required for the application processor 1001 to operate. In some embodiments, as shown, the DRAM 1060 may be positioned outside the application processor 1001. The DRAM 1060 may be packaged with the application processor 1001 in the form of a package on package (PoP).

At least one of the components of the SoC system 1000 may employ one of the semiconductor devices according to some embodiments.

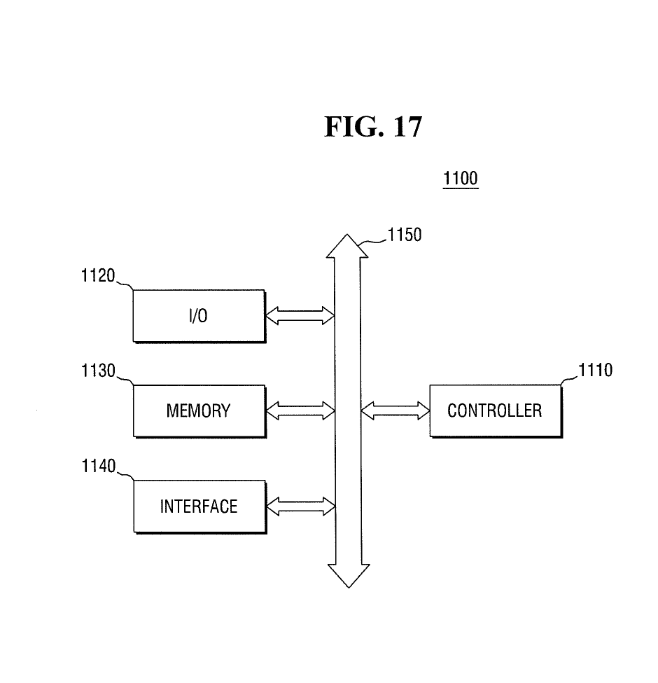

FIG. 17 illustrates a block diagram of an electronic system including semiconductor devices according to embodiments.

Referring to FIG. 17, the electronic system 1100 may include a controller 1110, an input/output device (I/O) 1120, a memory device 1130, an interface 1140 and a bus 1150. The controller 1110, the I/O 1120, the memory device 1130, and/or the interface 1140 may be connected to each other through the bus 1150. The bus 1150 corresponds to a path through which data moves.

The controller 1110 may include one or more of a microprocessor, a digital signal processor, a microcontroller, or logic elements capable of functions similar to those of these elements. The I/O 1120 may include a key pad, a key board, a display device, and so on. The memory device 1130 may store data and/or commands. The interface 1140 may perform functions of transmitting data to a communication network or receiving data from the communication network. The interface 1140 may be wired or wireless. For example, the interface 1140 may include an antenna or a wired/wireless transceiver, and so on.

The electronic system 1100 may further include high-speed DRAM and/or SRAM as a working memory for improving the operation of the controller 1110.

The aforementioned semiconductor devices according to the embodiments may be provided in the memory device 1130 or may be provided as some components of the controller 1110 or the I/O 1120.

The electronic system 1100 may be applied to a personal digital assistant (PDA), a portable computer, a web tablet, a wireless phone, a mobile phone, a digital music player, a memory card, or any type of electronic device capable of transmitting and/or receiving information in a wireless environment.

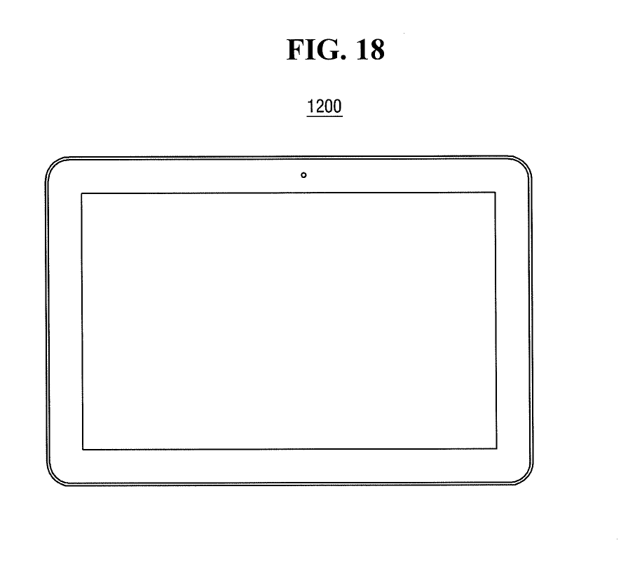

FIGS. 18 to 20 illustrate exemplary semiconductor systems to which semiconductor devices according to some embodiments may be applied.

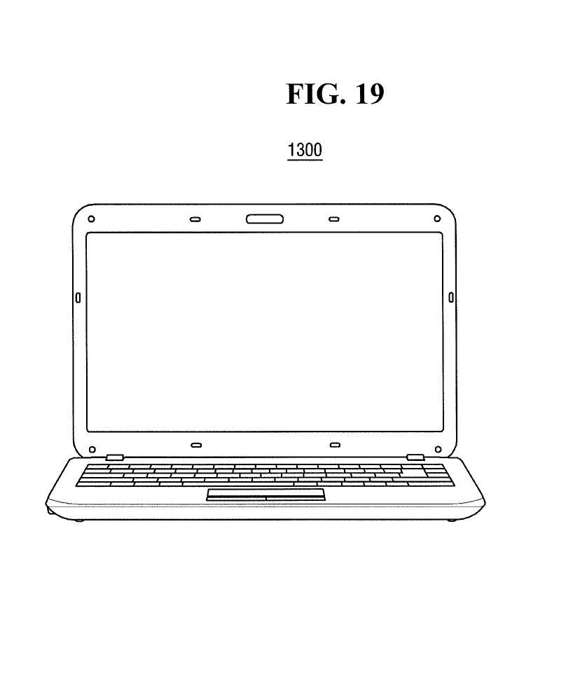

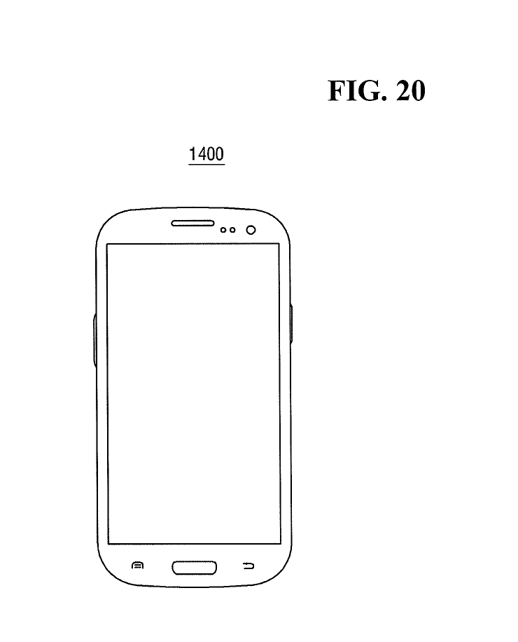

FIG. 18 illustrates an example in which a semiconductor device according to an embodiment is applied to a tablet PC (1200), FIG. 19 illustrates an example in which a semiconductor device according to an embodiment is applied to a notebook computer (1300), and FIG. 20 illustrates an example in which a semiconductor device according to an embodiment is applied to a smart phone (1400). At least one of the semiconductor devices according to some embodiments may be employed to, for example, a tablet PC 1200, a notebook computer 1300, or a smart phone 1400.

In the above-described embodiments, a tablet PC 1200, a notebook computer 1300 and a smart phone 1400 have been exemplified as the semiconductor devices according to the embodiments. The semiconductor devices according to some embodiments may also be applied to other IC devices not illustrated herein.

In some embodiments, the semiconductor system may be implemented as, for example, a computer, an ultra mobile personal computer (UMPC), a work station, a net-book, a personal digital assistant (PDA), a portable computer, a wireless phone, a mobile phone, an e-book, a portable multimedia player (PMP), a potable game console, a navigation device, a black box, a digital camera, a 3-dimensional (3D) television, a digital audio recorder, a digital audio player, a digital picture recorder, a digital picture player, a digital video recorder, or a digital video player.

By way of summation and review, a multi-gate transistor may use a three-dimensional channel, and scaling technology may be achieved. The current control capacity may be improved without increasing the gate length. Further, a short channel effect (SCE), in which the electric potential of the channel region may be affected by the drain voltage, may be effectively suppressed.

Provided is a semiconductor device that may have improved operating characteristics by improving its operating stability at high voltages.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A semiconductor device, comprising:
a first fin type pattern and a second fin type pattern defined by a trench, the first fin type pattern and the second fin type pattern extending in a first direction, the first fin type pattern and the second fin type pattern being closest to each other;
a field insulation layer filling a portion of the trench; and
a contact contacting the field insulation layer, the first fin type pattern, and the second fin type pattern, the contact having a bottom surface in a shape of a wave.

2. The semiconductor device as claimed in claim 1, wherein the bottom surface of the contact contacting the field insulation layer between the first fin type pattern and the second fin type pattern has a first point close to the first fin type pattern and a second point farther from the first fin type pattern than the first point, and a height ranging from a bottom of the trench to the first point is greater than a height ranging from the bottom of the trench to the second point.

3. The semiconductor device as claimed in claim 2, wherein a top surface of the first fin type pattern, a top surface of the second fin type pattern, and a top surface of the field insulation layer are curved surfaces in regions overlapping the contact.

4. The semiconductor device as claimed in claim 1, wherein:
an average thickness of the contact at a region where the contact overlaps with the top surface of the first fin type pattern is a first thickness, and an average thickness of the contact at a region where the contact overlaps with the top surface of the field insulation layer between the first fin type pattern and the second fin type pattern is a second thickness, and
the second thickness is greater than the first thickness.

5. The semiconductor device as claimed in claim 1, wherein the bottom surface of the contact is continuous along the top surface of the first fin type pattern, the top surface of the field insulation layer, and the top surface of the second fin type pattern.

6. The semiconductor device as claimed in claim 1, wherein sidewalls of the first fin type pattern and sidewalls of the second fin type pattern are entirely surrounded by the field insulation layer in regions overlapping the contact.

7. The semiconductor device as claimed in claim 6, wherein a width of the first fin type pattern at a first height from the bottom of the trench is a first width, a width of the first fin type pattern at a second height greater than the first height from the bottom of the trench is a second width, and the first width is greater than or equal to the second width.

8. The semiconductor device as claimed in claim 1, further comprising:
a third fin type pattern extending in the first direction; and
a gate electrode extending in a second direction different from the first direction, the gate electrode being on the first to third fin type patterns,
wherein the bottom surface of the contact is not in contact with the third fin type pattern.

9. The semiconductor device as claimed in claim 8, wherein:
a height ranging from the bottom of the trench to the topmost part of the first fin type pattern in a region where the contact and the first fin type pattern cross each other is a first height, and a height ranging from the bottom of the trench to the topmost part of the third fin type pattern in a region where an extension line of the contact extending in the second direction and the third fin type pattern cross each other is a second height, and
the second height is greater than the first height.

10. (canceled)

11. The semiconductor device as claimed in claim 1, wherein:
the field insulation layer includes a first part between the first fin type pattern and the second fin type pattern, a second part corresponding to the first part of the field insulation layer in view of the first fin type pattern, and a third part corresponding to the first part of the field insulation layer in view of the second fin type pattern, and
a height ranging from the bottom of the trench to a bottommost part of a top surface of the first part of the field insulation layer is different from a height ranging from the bottom of the trench to a bottommost part of a top surface of the second part of the field insulation layer and a height ranging from the bottom of the trench to a bottommost part of a top surface of the third part of the field insulation layer.

12. The semiconductor device as claimed in claim 11, wherein the height ranging from the bottom of the trench to a bottommost part of a top surface of the first part of the field insulation layer is greater than the height ranging from the bottom of the trench to the bottommost part of the top surface of the second part of the field insulation layer and the height ranging from the bottom of the trench to a bottommost part of a top surface of the third part of the field insulation layer.

13.-14. (canceled)

15. A semiconductor device, comprising:
a fin type pattern group including a plurality of fin type patterns defined by a first trench, the fin type pattern group extending in a first direction, the plurality of fin type patterns arranged in a second direction different from the first direction;
a field insulation layer filling a portion of the first trench;
a gate electrode extending on the field insulation layer in the second direction, the gate electrode intersecting the fin type pattern group;
an interlayer dielectric film on the field insulation layer, the interlayer dielectric film including a contact hole covering the fin type pattern group and the gate electrode, the contact hole extending in the second direction, the contact hole having a bottom surface defined by a top surface of the field insulation layer and a top surface of at least one fin type pattern, the bottom surface of the contact hole having a wave shape; and
a contact filling the contact hole on at least one side of the gate electrode.

16. The semiconductor device as claimed in claim 15, wherein the contact contacts the top surface of the fin type pattern and the top surface of the field insulation layer.

17. The semiconductor device as claimed in claim 15, wherein the bottom surface of the contact hole defined by the top surface of the fin type pattern has a ridge of a wave and the bottom surface of the contact hole defined by the top surface of the field insulation layer includes a valley of a wave.

18. The semiconductor device as claimed in claim 17, wherein the top surface of the fin type pattern group and the top surface of the field insulation layer exposed by the contact hole are curved surfaces.

19.-30. (canceled)

31. A semiconductor device, comprising:
a substrate;
fin patterns on the substrate;
a field insulation layer between the fin patterns; and
a contact overlapping and contacting at least some of the fin patterns and at least some of the field insulation layer between the fin patterns,
top surfaces of the fin patterns overlapped by the contact being upwardly convex, and top surfaces of the field insulation layer overlapped by the contact being downwardly convex.

32. The semiconductor device as claimed in claim 31, further comprising an additional contact, each of the contact and additional contact overlapping at least some of the fin patterns and at least some of the field insulation layer between the fin patterns,
wherein top surfaces of the fin patterns overlapped by each of the contacts are upwardly convex, and top surfaces of the field insulation layer overlapped by each of the contacts are downwardly convex.

33. The semiconductor device as claimed in claim 32, further comprising a gate electrode between the contacts.

34. The semiconductor device as claimed in claim 33, wherein the gate electrode extends in a direction different from a direction in which the fin patterns extend.

35. The semiconductor device as claimed in claim 34, wherein the gate electrode intersects the fin patterns.
